(19) United States
(12) Patent Application Publication
(10) Pub. No.: US 2020/0274097 A1
(43) Pub. Date: Aug. 27, 2020

(54) DISPLAY DEVICE, EXPOSURE DEVICE, AND MANUFACTURING METHOD OF DISPLAY DEVICE

(71) Applicant: SHARP KABUSHIKI KAISHA, Sakai City, Osaka (JP)

(72) Inventors: SHINJI ICHIKAWA, Sakai City, Osaka (JP); HIROKI TANIYAMA, Sakai City, Osaka (JP); SHINSUKE SAIDA, Sakai City, Osaka (JP); RYOSUKE GUNJI, Sakai City, Osaka (JP); TOHRU OKABE, Sakai City, Osaka (JP); YOSHIHIRO NAKADA, Yonago-shi, Tottori (JP); HIROHARU JINMURA, Yonago-shi, Tottori (JP); AKIRA INOUE, Yonago-shi, Tottori (JP)

(21) Appl. No.: 16/651,343

(22) PCT Filed: Sep. 29, 2017
(86) PCT No.: PCT/JP2017/035662

§ 371 Date: Mar. 26, 2020

(51) Int. Cl. H01L 51/52; H01L 51/56; H01L 27/32

(52) U.S. Cl. CPC H01L 51/5253; H01L 27/3218; H01L 27/3276; H01L 51/56

(57) ABSTRACT

A display device includes a plurality of picture elements. The plurality of picture elements are formed with anodes and cover layers cover an outer periphery of a corresponding anode of the anodes, the cover layer allowing an opening of the corresponding anode to be formed. The cover layer is spaced apart from the cover layer of a different anode of the anodes, the different anode being adjacent to the anode.

### TECHNICAL FIELD

The present invention relates to a display device and the like.

### BACKGROUND ART

Heretofore, various display devices, such as flat panel displays, are known (for example, refer to PTL 1). In general, display devices are formed by layering layers having various functions.

### CITATION LIST

### Patent Literature

PTL 1: JP 2015-22914 A (published on Feb. 2, 2015)

### SUMMARY OF INVENTION

### Technical Problem

In recent years, it is desired to increase the screen size of display devices and also to provide high-definition images. To achieve this, constituent elements of display devices are more and more miniaturized.

In a manufacturing process of a display device, a photolithography method is employed for fine processing. In the photolithography method, irradiation of a photosensitive resin with light is controlled using a photomask.

In a case where the screen size of a product to be manufactured is larger than a photomask, the photolithography method is used for a substrate having a larger size than that of the photomask. In this case, it is necessary to perform a step of disposing the photomask and then radiating light, several times.

However, in a case where the above-described step is performed several times, a surface of a resulting product in portions where edges of the photomask overlap may become uneven, and this may cause a problem.

An object of an aspect of the present invention is to provide a manufacturing method of a display device and a display device that can prevent any occurrence of a problem due to overlapping use of photomasks.

### Solution to Problem

A display device according to an aspect of the present invention is a display device including: a plurality of picture elements; first electrodes; and cover layers,

wherein the first electrodes are formed on the plurality of respective picture elements, each of the cover layers is configured to cover an outer periphery of a corresponding first electrode of the first electrodes, each of the cover layers allowing an opening of the corresponding first electrode to be formed, and a cover layer of the cover layers is spaced apart from a cover layer of the cover layers for a different first electrode of the first electrodes, the different first electrode being adjacent to the first electrode.

An exposure device according to an aspect of the present invention is an exposure device for performing pattern formation by a photolithography method on a photosensitive organic material film covering a plurality of first electrodes formed on a surface of a flattening film, the exposure device including: a light source configured to emit light to expose the photosensitive organic material film; and a photomask configured to block part of the light from the light source, wherein the photomask includes a semi-transparent portion configured to block part of the light from the light source and a transparent portion configured to allow the light to pass through, the semi-transparent portion allows, for the plurality of first electrodes, openings of the first electrodes and cover layers each covering an outer periphery of corresponding first electrode of the first electrodes, to be formed by light passing through the semi-transparent portion, and the transparent portion allowing a spacing region to be formed by the light passing through the transparent portion, the spacing region spacing at least parts of a plurality of the cover layers apart from each other.

An exposure device according to an aspect of the present invention is an exposure device for performing pattern formation by a photolithography method on a photosensitive organic material film covering a plurality of first electrodes formed on a surface of a flattening film, the exposure device including: a light source configured to emit light to expose the photosensitive organic material film; and a photomask configured to block part of the light from the light source, wherein the photomask includes a semi-transparent portion configured to block part of the light from the light source and a light blocking portion configured to block the light, the semi-transparent portion allows, for the plurality of first electrodes, openings of the first electrodes and cover layers each covering an outer periphery of corresponding first electrode of the first electrodes, to be formed by light passing through the semi-transparent portion, and the light blocking portion allows a spacing region to be formed by blocking the light by the light blocking portion, the spacing region spacing at least parts of a plurality of the cover layers apart from each other.

A manufacturing method of a display device according to an aspect of the present invention includes: a photosensitive layer forming step of covering a plurality of first electrodes formed on a surface of a flattening film, with a photosensitive organic material; and a cover layer forming step of exposing the photosensitive organic material, by using a photomask blocking part of light from a light source, and thereafter developing the photosensitive organic material, and thereby forming cover layers each covering an outer periphery of a corresponding first electrode of the plurality of first electrodes, the cover layer allowing an opening of the corresponding first electrode to be formed, wherein the photomask includes semi-transparent portions configured to block part of the light from the light source and a transparent portion configured to allow the light to pass through, and in the cover layer forming step, exposure is performed a plurality of times while changing a position of the photomask, and each of the cover layers is spaced apart from the cover layer of a different first electrode of the first electrodes, the different first electrode being adjacent to the first electrode.

### Advantageous Effects of Invention

According to an aspect of the present invention, it is possible to prevent any occurrence of a problem due to overlapping use of photomasks.

### BRIEF DESCRIPTION OF DRAWINGS

FIG. 1 is a flowchart illustrating an example of a method of manufacturing a display device.

FIG. 2 is a cross-sectional view illustrating a configuration example of a display portion of the display device.

FIG. 3 is a plan view illustrating a configuration example of the display device.

FIG. 4 is a cross-sectional view illustrating a method of forming cover layers and spacers, and (a) illustrates a state before baking while (b) illustrates a state after the baking.

FIG. 5 is a plan view illustrating an arrangement of subpixels, cover layers, and spacers in the display device.

FIG. 6 is a block diagram illustrating a configuration of a film formation device.

FIG. 7 is a conceptual diagram illustrating a configuration of an exposure device.

FIG. 8 is a plan view schematically illustrating an example of a configuration of a photomask.

FIG. 9 is a diagram for describing an advantageous effect of an exposure method according to the present embodiment.

FIG. 10 is a cross-sectional view illustrating a configuration example of a display portion of a display device according to a comparative example.

FIG. 11 is a plan view illustrating an arrangement of subpixels, cover layers, and spacers in the display device according to the comparative example.

FIG. 12 is a flowchart illustrating an example of a flow of a procedure at the film formation device.

FIG. 13 is a block diagram illustrating a configuration of an EL device manufacturing apparatus.

FIG. 14 is a plan view illustrating an example of a configuration of a negative-working photomask.

FIG. 15 is a cross-sectional view illustrating a configuration example of a display portion of a display device according to a fourth embodiment.

FIG. 16 is a plan view illustrating a configuration of a display region and a periphery of the display region.

FIG. 17 is a cross-sectional view taken along a line A-A in FIG. 16.

### DESCRIPTION OF EMBODIMENTS

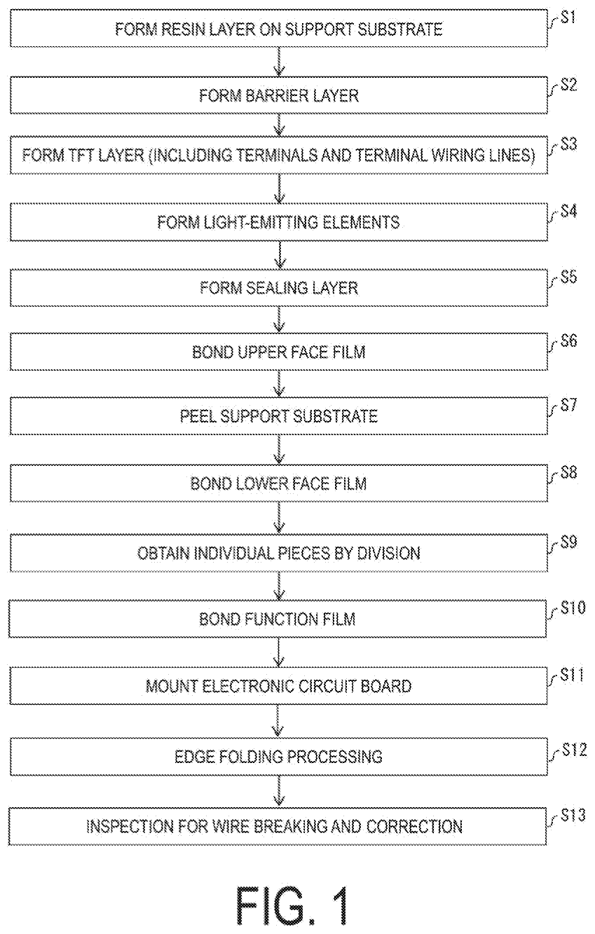

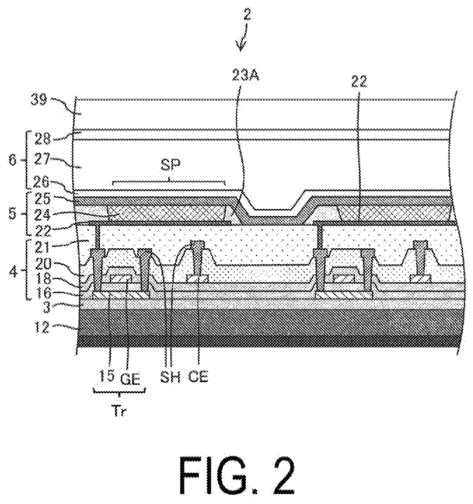

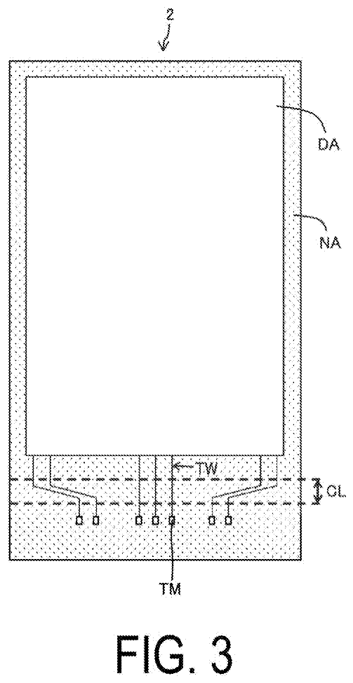

FIG. 1 is a flowchart illustrating an example of a manufacturing method of a display device (electronic device). FIG. 2 is a cross-sectional view illustrating a configuration example of a display portion of the display device. FIG. 3 is a plan view illustrating a configuration example of the display device. In the following, a “same layer” refers to a layer formed in the same process using the same material, a “lower layer” refers to a layer formed in a process before the layer being compared, and an “upper layer” refers to a layer formed in a process after the layer being compared.

When the flexible display device is manufactured, as illustrated in FIGS. 1 to 3, first, a resin layer 12 is formed on a transparent support substrate (a mother glass substrate, for example) (step S1). Next, a barrier layer 3 is formed (step S2). Next, a TFT layer 4 including terminals TM and terminal wiring lines TW is formed (step S3). Next, a top-emitting type light-emitting element layer (for example, an organic light emitting diode (OLED) element layer) 5 is formed (step S4). Next, a sealing layer 6 is formed (step S5). Next, an upper face film is bonded to the sealing layer 6 (step S6).

Next, a lower face of the resin layer 12 is irradiated with laser light through the support substrate to reduce a bonding force between the support substrate and the resin layer 12, and the support substrate is peeled from the resin layer 12 (step S7). Next, a lower face film 10 is bonded to the lower face of the resin layer 12 (step S8). Next, a layered body including the lower face film 10, the resin layer 12, the barrier layer 3, the TFT layer 4, the light-emitting element layer 5, and the sealing layer 6 is divided and a plurality of individual pieces are obtained (step S9). Next, a function film 39 is bonded on the obtained individual pieces (step S10). Next, an electronic circuit board (an IC chip, for example) is mounted on a terminal for external connection (step S11). Next, edge folding processing (processing of bending a bending portion CL in FIG. 3 at a 180-degree) is performed to make a display device 2 (step S12). Next, an inspection for wire breaking is performed, and in a case where there is breaking of any wire, correction is performed (step S13). Note that each of the steps is performed by a display device manufacturing apparatus described below.

Examples of the material of the resin layer 12 include polyimide, epoxy, and polyamide. Examples of the material of the lower face film 10 include polyethylene terephthalate (PET).

The barrier layer 3 is a layer that inhibits moisture or impurities from reaching the TFT layer 4 or the light-emitting element layer 5 when the display device is being used, and can be constituted by a silicon oxide film, a silicon nitride film, or a silicon oxynitride film, or by a layered film of these, for example, formed using chemical vapor deposition (CVD).

The TFT layer 4 includes a semiconductor film 15, an inorganic insulating film 16 (a gate insulating film) in an upper layer overlying the semiconductor film 15, gate electrodes GE in an upper layer overlying the inorganic insulating film 16, an inorganic insulating film 18 in an upper layer overlying the gate electrodes GE, capacitance wiring lines CE in an upper layer overlying the inorganic insulating film 18, an inorganic insulating film 20 in an upper layer overlying the capacitance wiring lines CE, source wiring lines SH and terminals TM in an upper layer overlying the inorganic insulating film 20, and a flattening film 21 in an upper layer overlying the source wiring lines SH and the terminals TM.

Each thin-film transistor Tr (TFT) includes the semiconductor film 15, the inorganic insulating film 16 (the gate insulating film), and the gate electrode GE.

In a non-display region NA of the TFT layer 4, the terminals TM to be used for connection with an electronic circuit board such as an IC chip or an FPC, and terminal wiring lines TW (to be described later in detail) for connecting the terminals TM and wiring lines of an active area DA and the like, are formed.

The semiconductor film 15 is formed of low-temperature polysilicon (LTPS) or an oxide semiconductor, for example. Note that, although the TFT provided with the semiconductor film 15 as the channel is illustrated as having a top gate structure in FIG. 2, the TFT may have a bottom gate structure (when the TFT channel is an oxide semiconductor, for example).

Each of the gate electrodes GE, the capacitance electrodes CE, the source wiring lines SH, the terminal wiring lines TW, and the terminals TM is formed of, for example, a monolayer film or a layered film of metal containing at least one of aluminum (Al), tungsten (W), molybdenum (Mo), tantalum (Ta), chromium (Cr), titanium (Ti), and copper (Cu).

Each of the inorganic insulating films 16, 18, and 20 can be formed of, for example, a silicon oxide (SiOx) film or a silicon nitride (SiNx) film, or a layered film of these, formed using CVD.

The flattening film (interlayer insulating film) 21 can be formed of, for example, a coatable photosensitive organic material, such as a polyimide, an acrylic, or the like.

The light-emitting element layer 5 (an organic light emitting diode layer, for example) includes anodes 22 in an upper layer overlying the flattening film 21, cover layers 23A each including an organic film as an electrode edge cover covering an edge of a corresponding one of the anodes 22 (reflective electrodes), spacers 23B to be described later, electroluminescence (EL) layers 24 in an upper layer overlying the anodes 22, and a cathode 25 in an upper layer overlying the EL layers 24. A light-emitting element (an organic light emitting diode (OLED), for example) including the anode 22 having an island shape, the EL layer 24, and the cathode 25, and a subpixel circuit for driving the light-emitting element are provided on a per subpixel 29 (picture element) basis. Each of the cover layers 23A and the spacers 23B is an organic film formed from a photosensitive organic material, and is formed by a film formation device 30 to be described later.

For example, the EL layers 24 are formed by layering a hole injection layer, a hole transport layer, a light-emitting layer, an electron transport layer, and an electron injection layer in this order, from the lower layer side. The light-emitting layer is formed in an island shape for each subpixel 29 by a vapor deposition method or ink-jet method, but the other layers may be a solid-like common layer. A configuration is also possible in which one or more layers are not formed, out of the hole injection layer, the hole transport layer, the electron transport layer, and the electron injection layer.

The anodes (anode electrodes) 22 are formed by layering of Indium Tin Oxide (ITO) and silver (Ag) or alloy containing Ag, for example, and have light reflectivity (to be described later in detail). The cathode 25 may be formed of a transparent conductive material such as Indium Tin Oxide (ITO) or Indium zinc Oxide (IZO).

In a case where the light-emitting element layer 5 is an OLED layer, positive holes and electrons are recombined inside each EL layer 24 by a drive current between the corresponding anode 22 and the cathode 25, and light is emitted as a result of excitons that are generated by the recombination falling into a ground state. Since the cathode 25 is transparent and the anode 22 has light reflectivity, the light emitted from the EL layer 24 travels upward and becomes top-emitting.

The light-emitting element layer 5 may be used not only in a case of constituting the OLED element, but also in a case of constituting an inorganic light emitting diode or quantum dot light emitting diode.

The sealing layer 6 is transparent, and includes a first inorganic sealing film 26 that covers the cathode 25, an organic sealing film 27 that is formed on the first inorganic sealing film 26, and a second inorganic sealing film 28 that covers the organic sealing film 27. The sealing layer 6 covering the light-emitting element layer 5 inhibits foreign matter, such as water and oxygen, from penetrating to the light-emitting element layer 5.

Each of the first inorganic sealing film 26 and the second inorganic sealing film 28 may be formed of, for example, a silicon oxide film, a silicon nitride film, or a silicon oxynitride film, or of a layered film of these, formed through CVD. The organic sealing film 27 is thicker than the first inorganic sealing film 26 and the second inorganic sealing film 28, is a light-transmissive organic film, and can be formed of a coatable photosensitive organic material such as polyimide or acrylic.

The lower face film 10 is a film bonded on the lower face of the resin layer 12 after the support substrate is peeled off, for achieving a display device with excellent flexibility, and examples of the material of the lower face film 10 include PET. The function film 39 has an optical compensation function, a touch sensor function, a protection function, or the like, for example.

In the above, the case of manufacturing a flexible display device is described, but in the case of manufacturing a non-flexible display device, since the substrate does not need to be replaced, the process proceeds from step S5 to step S9 in FIG. 1, for example.

### First Embodiment

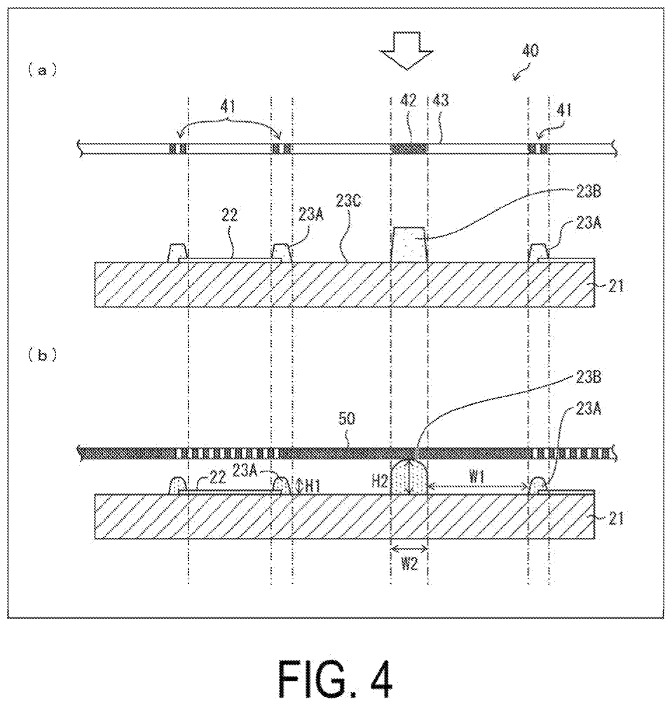

FIG. 4 is a cross-sectional view illustrating a method of forming the cover layers 23A and the spacers 23B in a display device 2 according to the present embodiment. (a) of FIG. 4 illustrates a state before baking while (b) of FIG. 4 illustrates a state after the baking. As illustrated in (a) of FIG. 4, the cover layers 23A and the spacers 23B are organic films formed in the same layer on the surface of the flattening film 21, and are patterned by a photolithography method. Each of the cover layers 23A and the spacers 23B may be formed of, for example, a coatable photosensitive organic material, such as polyimide or acrylic.

Each of the cover layers 23A covers the entire circumference of the edges of a corresponding one of the plurality of anodes 22 (first electrodes) and forms an opening in the anode 22. Each of the spacers 23B are formed between a plurality of the cover layers 23A.

Each cover layer 23A is an organic film covering the edge of the anode 22, which is a reflective electrode, and has a role as an electrode edge cover that defines the outer edge shape of the exposed surface of the anode 22. More specifically, the cover layer 23A is formed along an edge of a corresponding one of the plurality of anodes 22 and covers the entire circumference of the edges of the anode 22 (see FIG. 8). As illustrated in FIG. 2, the cover layer 23A is formed between the flattening film 21 and the cathode 25 (a second electrode) and is located at an outer edge portion of a corresponding one of the subpixels 29, which are light-emitting elements. The cover layer 23A is formed such that the anode 22 and the cathode 25 do not short each other.

The spacers 23B are banks that serve as spacers at the time of disposing a vapor deposition mask 50, and are formed on the surface of the flattening film 21. As illustrated in (b) of FIG. 4, each of the spacers 23B after baking has a height H2 from the surface of the flattening film 21 greater than a height H1 of the cover layer 23A. The height H2 is 2 to 5 μm, for example, and the height H1 is 1 to 3 μm, for example.

The vapor deposition mask 50 is a mask for depositing vapor deposition particles (for example, an organic light-emitting material) that form light-emitting layers in the EL layers 24, and includes a plurality of through-holes corresponding to a desired vapor deposition pattern. Each of the EL layers 24 is layered on a corresponding one of the anodes 22, and the cathode 25 facing the anode 22 is formed in an upper layer of the layered EL layer 24. In other words, the EL layer 24 including the light-emitting layer is formed between the anode 22 and the cathode 25. The cover layers 23A and the spacers 23B may also be described as being formed between the flattening film 21 and the cathode 25.

The spacers 23B are formed on the surface of the flattening film 21 to be spaced apart from the cover layers 23A. Moreover, at least parts of the plurality of cover layers 23A covering the plurality of respective anodes 22 are formed to be spaced apart from each other. Note that all of the cover layers 23A need not be formed to be apart from each other.

Each region between each cover layer 23A and the corresponding spacer 23B or each region between two cover layers 23A is referred to as a spacing region 23C. A distance W1 (i.e., the width of the spacing region 23C) between the cover layer 23A and the spacer 23B is 10 to 20 μm, for example. The outer edge portion of the cover layer 23A and the outer edge portion of the spacer 23B may be formed at an interval greater than or equal to the resolution (for example, greater than or equal to 2 μm) of the exposure device 33 to be used. A width W2 of each spacer 23B itself is not particularly limited, but is 8 to 12 μm, for example.

As illustrated in FIG. 4, in a case where a physical load is applied directly to the cover layers 23A at the time of disposing the vapor deposition mask 50, the cover layers 23A may be damaged. In a case where any cover layer 23A is damaged, this may possibly cause the corresponding anode 22 and the cathode 25 to be shorted, and for this reason, it is preferable to prevent any damage to the cover layers 23A. In view of this, the spacers 23B having a height greater than that of the cover layers 23A are provided so that the spacers 23B receive the load, to thereby prevent any damage to the cover layers 23A.

In a case where the cover layers 23A and the spacers 23B are integrally formed, the spacers 23B are absorbed by the cover layers 23A due to heat sagging through baking. This makes it difficult to achieve a desired height of the spacers 23B. Forming the spacing regions 23C around each spacer 23B to space the spacers 23B apart from the cover layers 23A can prevent heat sagging of the spacers 23B. One factor of this is surface tension. In a case where a material is surrounded by no material in the same state, it is difficult for the material to spread out. However, in a case where no such effect is required, the spacers 23B and the cover layers 23A may be formed integrally. Alternatively, the cover layers 23A may be provided with no spacer 23B being provided. In this case, protrusions may be provided on the vapor deposition mask 50.

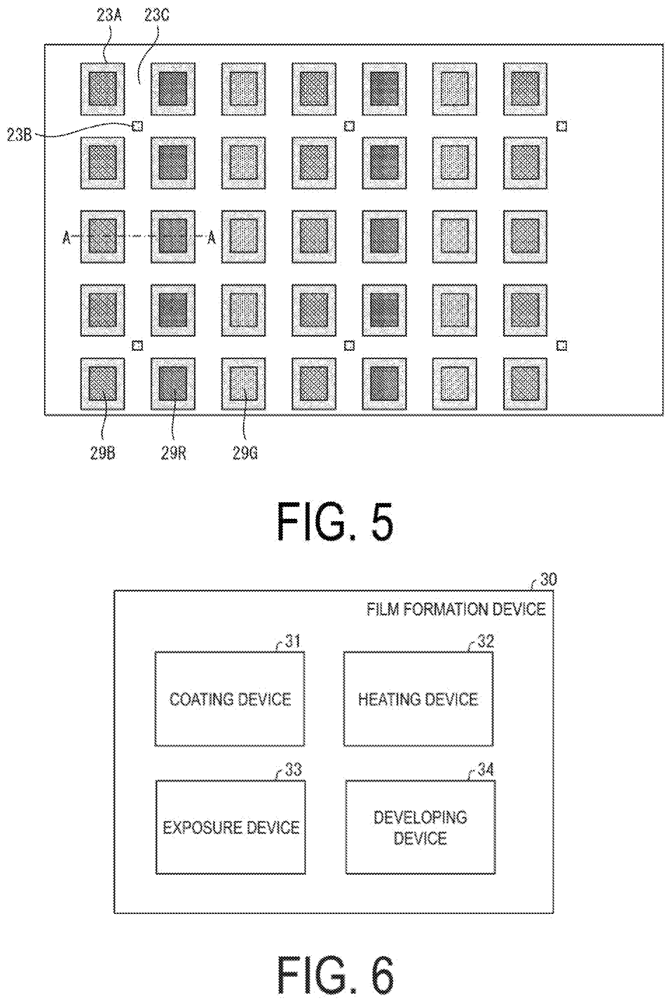

FIG. 5 is a plan view illustrating an arrangement of the subpixels 29, the cover layers 23A, and the spacers 23B in the display device 2. The cross-sectional view taken along a line A-A in FIG. 5 is a cross-sectional view of a configuration example of the display device 2 illustrated in FIG. 2.

As illustrated in FIG. 5, each of the cover layers 23A is formed to cover an outer periphery of the corresponding anode 22. As a result, an open region of the anode 22 is formed, and the EL layer 24 is formed in the opening region. The display device 2 includes, as the subpixels 29, subpixels (pixel elements) of three colors, i.e., red pixel elements 29R, blue pixel elements 29B, and green pixel elements 29G. One pixel is represented by these three pixel elements. However, the pixel elements included in the display device 2 are not limited to the three colors of R, G, and B, and are not particularly limited, such as by adding white or yellow to include pixel elements of four or more colors.

As illustrated in FIG. 5, the cover layers 23A are formed only around the subpixels 29, and the spacers 23B are formed in parts of the regions where no cover layer 23A is formed. The outer edge portion of each of the cover layers 23A and the outer edge portion of another one of the cover layers 23A are spaced apart from each other, and the outer edge portion of each of the cover layers 23A and the outer edge portion of the corresponding spacer 23B are spaced apart from each other.

FIG. 6 is a block diagram illustrating a configuration of the film formation device 30. The film formation device 30 is a device configured to pattern the cover layers 23A and the spacers 23B by a photolithography method, and as illustrated in FIG. 6, includes a coating device 31, a heating device 32, an exposure device 33, and a developing device

The coating device 31 is a device configured to apply a photosensitive organic material for forming the cover layers 23A and the spacers 23B to the surface of the flattening film 21. As the coating device 31, for example, a spin coating or a slit coating type coating device can be used.

The heating device 32 is a heater for prebaking.

The exposure device 33 is a device configured to perform pattern formation by the photolithography method. The exposure device 33 irradiates the applied photosensitive organic material (photosensitive organic material film) with light passing through the photomask 40, to thereby increase the solubility in a developing solution for a part of the photosensitive organic material.

The developing device 34 is a device configured to remove the irradiated part of the photosensitive organic material in the developing solution.

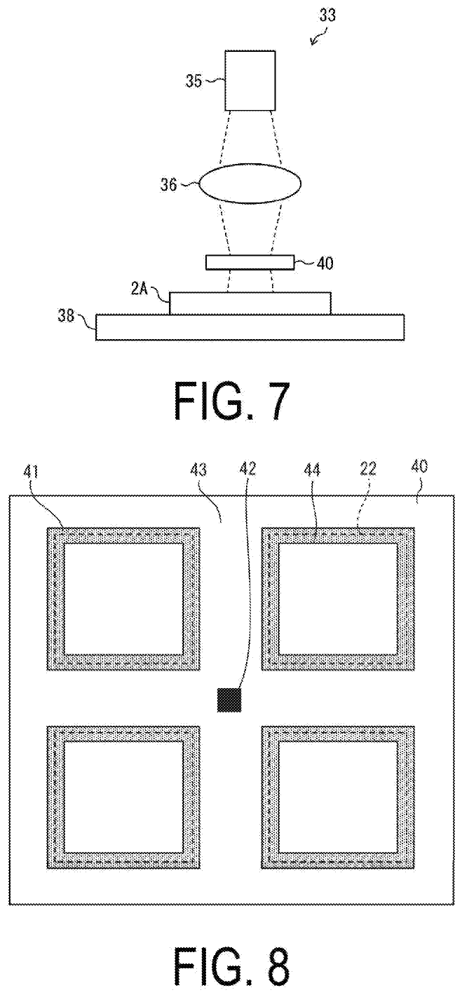

FIG. 7 is a conceptual diagram illustrating a configuration of the exposure device 33. As illustrated in FIG. 7, the exposure device 33 includes a light source 35, a light collection optical system 36, the photomask 40, and a stage 38 for placing a display device 2A under manufacturing.

Distribution of light emitted from the light source 35 (hereinafter referred to as emitted light) is controlled by the light collection optical system 36, and the photomask 40 is irradiated with the resultant light. A known light source such as a high-pressure mercury lamp can be used as the light source 35, and a wavelength suitable for the photosensitive organic material to be used may be selected for the wavelength of the emitted light. A g-line, an h-line, an i-line, or a mixed wavelength thereof, or the like can be used as the wavelength.

FIG. 8 is a plan view schematically illustrating an example of a configuration of the photomask 40. The photomask 40 is a mask for realizing an exposure pattern corresponding to desired shapes of the cover layers 23A and the spacer 23B by allowing only part of the emitted light to pass through.

As illustrated in FIG. 8, semi-transparent regions 41 (semi-transparent portions) for forming the cover layers 23A, a light blocking region 42 (a light blocking portion) for forming the spacer 23B, and a transparent region 43 (a transparent portion) are formed in the photomask 40. The transparent region 43 is a region between the semi-transparent regions 41 and the light blocking region 42.

As illustrated in FIG. 4 described above, the cover layers 23A are formed directly under the semi-transparent regions 41, the spacer 23B is formed directly under the light blocking region 42, and the spacing region 23C is formed directly under the transparent region 43, during the exposure process.

The semi-transparent regions 41 are regions allowing the emitted light to partially pass through. In the semi-transparent regions 41, a number of fine openings or fine slits that cannot be resolved by the exposure device to be used are formed. With the light passing through the semi-transparent regions 41, the height H1 of the cover layers 23A is lowered without the cover layers 23A being completely removed in the developing step. Hence, the height H1 of the cover layers 23A can be set by the transmittance of the fine openings or fine slits in the semi-transparent regions 41. The light transmittance of the semi-transparent regions 41 may be set to a preferable value depending on the desired height of the cover layers 23A.

The light blocking region 42 is a region blocking the emitted light nearly 100%. For this reason, the film surface of the spacer 23B corresponding to the light blocking region 42 is not affected by the emitted light, and the height H2 of the spacer 23B is not reduced by the exposure. The light blocking region 42 illustrated in FIG. 8 has a rectangular shape, but the light blocking region 42 may have a polygon shape such as a triangle, or may have a different shape such as a circle, a semicircle and an ellipse. The size of the light blocking region 42 may also be set to a size that ensures the width required for the spacer 23B to function as a spacer.

The light blocking region 42 is formed between regions corresponding to the anodes 22 (regions indicated by dashed lines in FIG. 8). The shape of the anodes 22 is not particularly limited, and the anodes 22 may have a different shape, such as a diamond shape or a circular shape, from the shape illustrated in FIG. 8.

The forming position and the formation interval of the light blocking regions 42 are not particularly limited, and may be formed on the left and right or the upper and lower sides of the region corresponding to each of the anodes 22, or may be provided on the left and right and the upper and lower sides of the region. One light blocking region 42 may be formed for the anode 22 or may be formed for a predetermined number of anodes 22. In other words, the numerical and positional relationships between the spacers 23B and the anodes 22 can be arbitrarily set.

The transparent region 43 is a region allowing the emitted light to pass through. Hence, the solubility of the photosensitive organic material directly under the transparent region 43 is increased by the exposure, to be completely removed in the developing step. As a result, spacing regions 23C are formed.

Transparent regions 44 (transparent portions) for defining outer edges of the exposed surfaces of the anodes 22 are formed in the photomask 40. With the light passing through the transparent regions 44, the solubility of part of the photosensitive organic material covering a surface of the corresponding anode 22 increases, to expose the part of the surface of the anode 22. By using the above-described photomask 40, the cover layers 23A, the spacer 23B, and the exposed surfaces of the anodes 22 can be formed by performing the photolithography method once.

### Effects of Present Embodiment

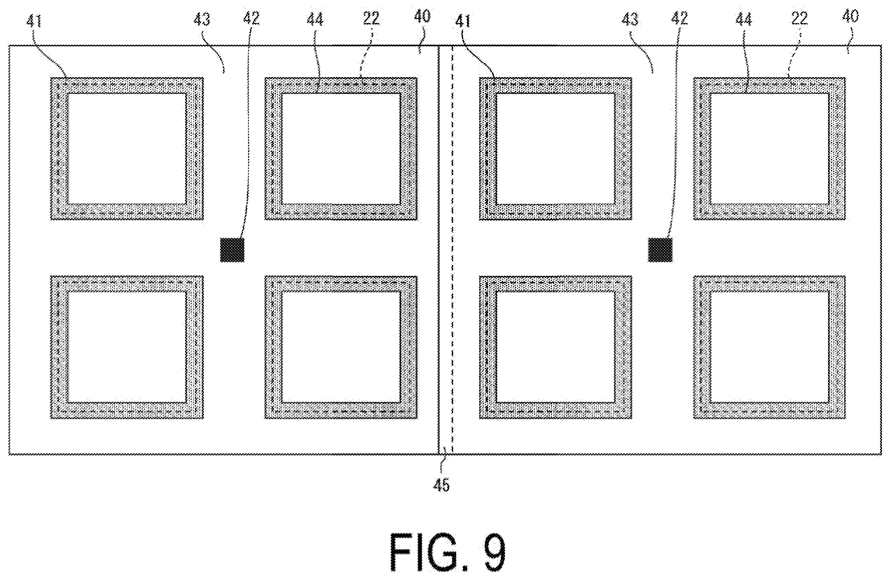

FIG. 9 is a diagram for describing an advantageous effect of an exposure method according to the present embodiment. In FIG. 9, only four semi-transparent regions 41 and four transparent regions 44 are illustrated for one photomask 40 for convenience. In a case of forming the display device 2 having a screen size greater than that of a photomask on a large mother glass substrate, the photosensitive organic material is applied to the flattening film 21 having the surface on which the anodes 22 are formed, and thereafter exposure is performed a plurality of times while changing the position of the photomask 40 with respect to the mother glass substrate in that state. FIG. 9 illustrates a virtual state in which two photomasks 40 overlap in the exposure step. Each of the cover layers 23A and the spacers 23B are formed in an island pattern. Since an overlapping region 45 where the two photomasks 40 overlap each other corresponds to the transparent region 43, this prevents any cover layer 23A from being formed directly under the overlapping region 45. Hence, there is no problem in the shape of the cover layers 23A directly under the overlapping region 45.

As described above, in the present embodiment, the overlapping region 45 may correspond to the transparent region 43, and hence the photomask 40 can be arranged in an overlapping manner in the overlapping region 45. In this way, any occurrence of a problem due to overlapping use of the photomask 40 can be prevented.

A photosensitive organic material in a wide range is irradiated with light in the transparent region 43. This allows the developing solution to readily enter the spacing regions 23C at the time of developing using the developing device 34, and consequently allows the photosensitive organic material to readily dissolve. Moreover, the amount of the cover layers 23A is reduced with the spacing regions 23C being formed. As a result, moisture and impurities originating from the photosensitive organic material can be prevented from contaminating the light-emitting element layer 5. It is also possible to dispose a layer having a function of preferentially adsorbing moisture in each of the spacing regions 23C.

In the present embodiment, in a case of providing the spacers 23B, it is possible to prevent the spacers 23B from being absorbed by the cover layers 23A due to heat sagging as described above. Hence, it is not necessary to increase the area of the region of each of the spacers 23B in order to achieve the desired height, and this can reduce the region of the spacers 23B. This is an advantage in manufacturing high-definition display panels.

It is also possible for the cover layers 23A each formed in an island pattern, to prevent heat sagging during baking. Hence, it may be easier for the cover layers 23A to have the desired height and to have clear edges.

### COMPARATIVE EXAMPLE

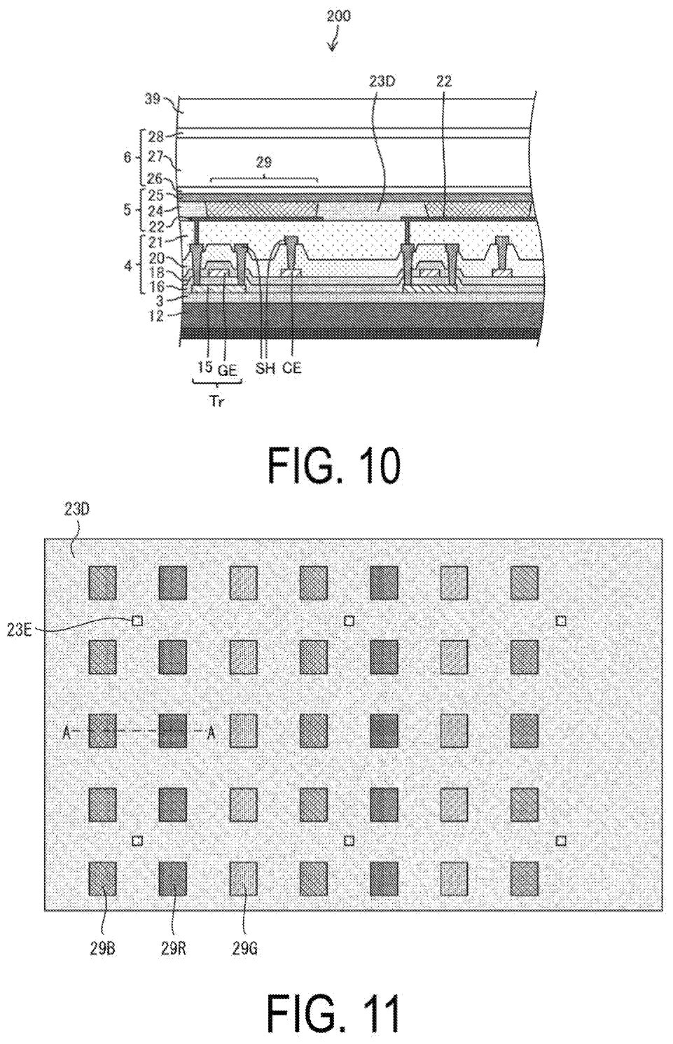

FIG. 10 is a cross-sectional view illustrating a configuration example of a display portion of a display device 200 according to a comparative example. FIG. 11 is a plan view illustrating an arrangement of the subpixels 29, a cover layer 23D, and spacers 23E in the display device 200 according to the comparative example. A cross-sectional view taken along a line A-A in FIG. 11 is illustrated in FIG. 10. The display device 200 is different from the display device 2 in that the display device 200 includes the cover layer 23D and the spacers 23E.

As illustrated in FIG. 10 and FIG. 11, in the conventional display device 200 (for example, the display device described in PTL 1), no spacing region 23C is formed, and the cover layer 23D is formed on the entire surface of the anodes 22. In other words, for example, exposure used to be performed by using a photomask in which the entire transparent region 43 is formed as the semi-transparent region 41. In the conventional display device 200 described above, the surface of the photosensitive organic material directly under the overlapping region 45 illustrated in FIG. 8 may be uneven, and this may cause a problem.

### Flow of Process According to Present Embodiment

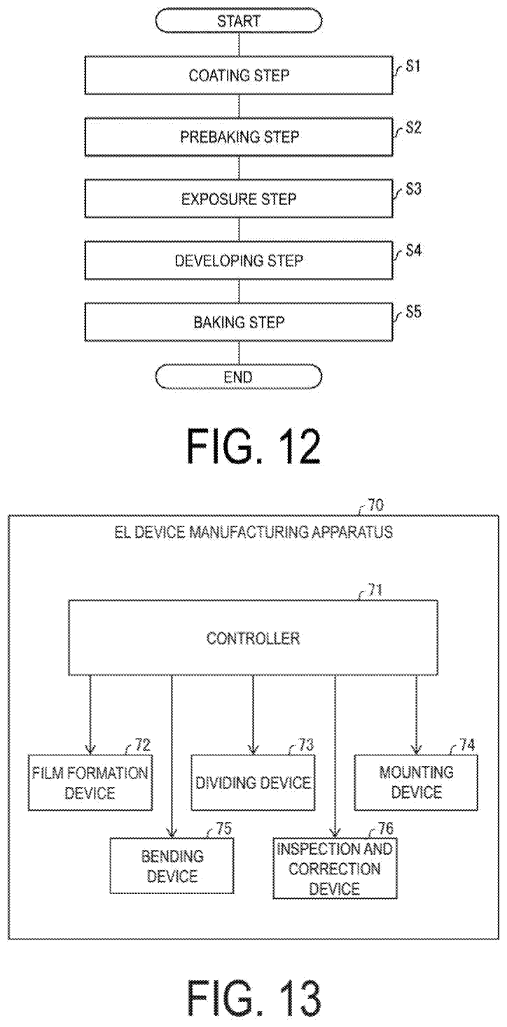

FIG. 12 is a flowchart illustrating an example of a flow of a process in the film formation device 30 (a photolithography step). First, the coating device 31 applies the photosensitive organic material to the surface of the flattening film 21 (S1).

Thereafter, the display device 2A is brought into the heating device 32 to be prebaked at 90 to 120° C., for example (S2). S1 and S2 are referred to as photosensitive layer forming steps.

After the heating, the exposure device 33 performs an exposure process (S3). First, the exposure device 33 positions the photomask 40 relative to the photosensitive organic film to be exposed. Then, the exposure device 33 turns on light of the light source 35 and irradiates the organic film with emitted light through the photomask 40. This step is performed a plurality of times while changing the position of the photomask 40 with respect to the mother glass substrate.

The display device 2A thus exposed is developed in the developing device 34 to form the cover layers 23A and the spacers 23B having shapes corresponding to the pattern of the photomask 40 (S4).

Finally, the display device 2A is brought into a heating device (not illustrated) and is baked at 200 to 250° C., for example (S5). S3, S4, and S5 are referred to as cover layer forming steps.

After the cover layers 23A and the spacers 23B are formed, an organic light-emitting material vaporized or sublimated by a vapor deposition source is deposited on the anodes 22 through the vapor deposition mask 50 in a vacuum to form the EL layers 24 (organic layers) (deposition step). In this step, the vapor deposition is performed while the vapor deposition mask 50 is abutting against the spacers 23B. The vapor deposition method is not particularly limited, and a known method may be used. Such a manufacturing method of the display device 2 is also included within the technical scope of the present disclosure.

### Other Configurations

The spacers 23B are not limited to forming the spacers 23B on the surface of the flattening film 21. For example, the spacers 23B may be formed on the anodes 22 that are insulated or may be formed on an inorganic film.

### Second Embodiment

FIG. 13 is a block diagram illustrating a configuration of a manufacturing apparatus of the display device 2. As illustrated in FIG. 13, an EL device manufacturing apparatus 70 for manufacturing the display device 2 includes a film formation device 72, a dividing device 73, a mounting device 74, a bending device 75, and an inspection and correction device 76, and also a controller 71 configured to control these devices. The film formation device 30 is included in the EL device manufacturing apparatus 70 as one example of the film formation device 72.

Thus, the EL device manufacturing apparatus 70 including the film formation device 30 is also included within the technical scope of the present disclosure.

### Third Embodiment

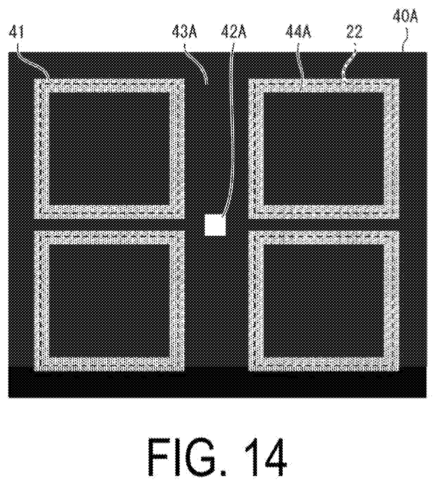

Although the photomask 40 for performing a positive-working photolithography method is illustrated in FIG. 8, the exposure device 33 may include a negative-working photomask 40A. FIG. 14 is a plan view illustrating an example of a configuration of a negative-working photomask 40A. In the photomask 40A, a region corresponding to the light blocking region 42 is a transparent region 42A (a transparent portion), and a region corresponding to the transparent region 43 is a light blocking region 43A (a light blocking portion). Regions corresponding to the transparent regions 44 are light blocking regions 44A (light blocking portions).

In the negative-working photolithography method, the photosensitive organic material is removed at each location not irradiated with light emitted from the light source 35, in the developing step.

### Fourth Embodiment

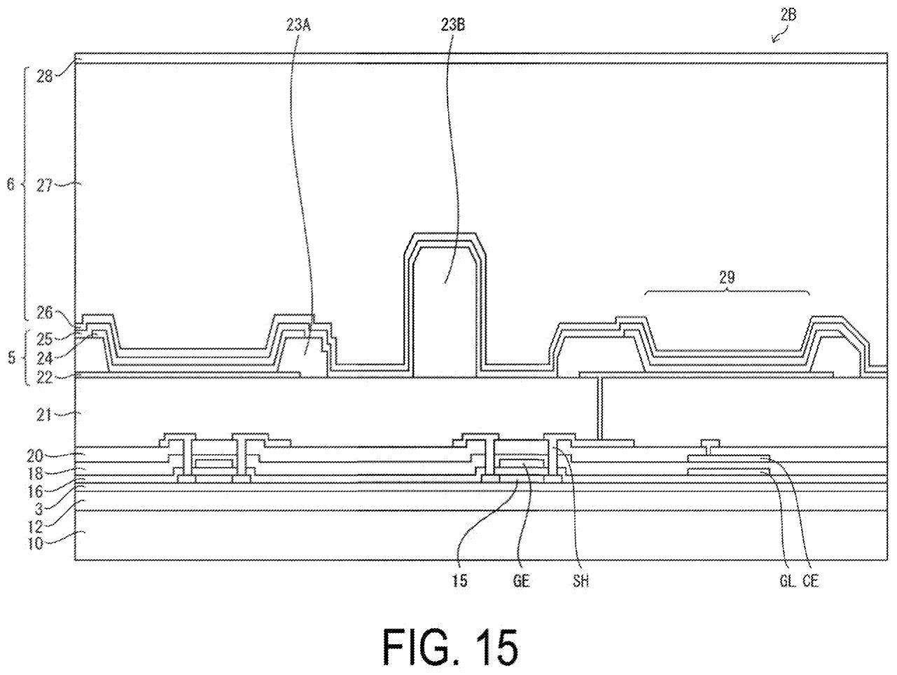

FIG. 15 is a cross-sectional view illustrating a configuration example of a display portion of a display device 2B according to the present embodiment. As an example of a specific configuration, the display device 2B may be configured as illustrated in FIG. 15. The display device 2B is different from the display device 2 of the first embodiment described above in that the gate wiring lines GL are formed below the capacitance wiring lines CE, and that the light-emitting element layer 5 has an uneven shape. In FIG. 15, a cross section of the display device 2B including the spacer 23B is illustrated. The portions illustrated in FIG. 15 are similar to those described in the first embodiment described above by using FIG. 2, and hence descriptions thereof are omitted for the sake of simplicity.

### Fifth Embodiment

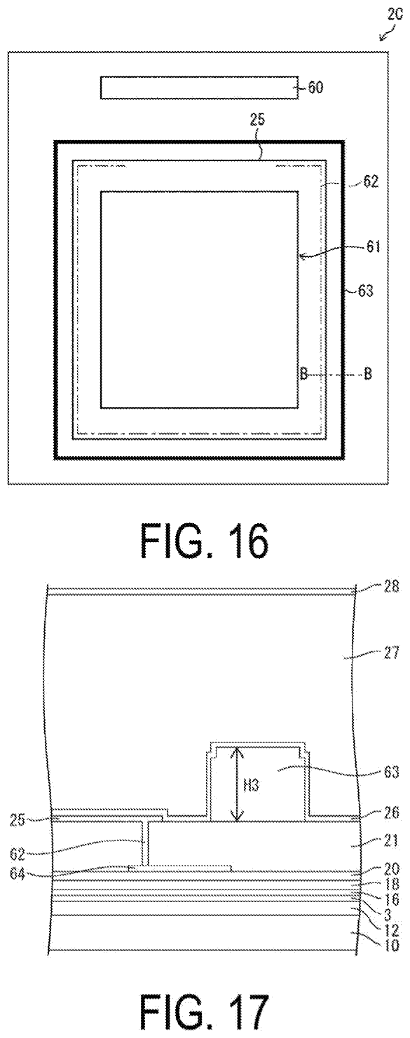

FIG. 16 is a plan view illustrating a configuration of a display region and a periphery thereof. FIG. 17 is a cross-sectional view taken along a line B-B in FIG. 16. As illustrated in FIG. 16, slits 62 are formed to surround a display region 61, which is a region including the plurality of subpixels 29. The slits 62 are contact holes for communicating the cathode 25 and wiring lines 64 of the TFT layer 4. A frame-shaped spacer 63 having a frame shape is formed to surround the slits 62. A terminal portion 60 is formed on an outer side of the frame-shaped spacer 63.

The display device 2C according to the present embodiment may have, in the display region 61, a similar configuration to that of the display device 2B described in the fourth embodiment by using FIG. 15. In other words, the display device 2C may have a configuration in which the frame-shaped spacer 63 is provided at an end portion of the display device 2B.

As illustrated in FIG. 17, an outer edge portion of the cathode 25, which is formed to cover the display region 61, is communicated with the wiring lines 64 of the TFT layer 4 by the slits 62. The slits 62 are formed in the flattening film 21, and the cathode 25 and the wiring lines 64 of the TFT layer 4 are electrically communicated through the slits 62.

A height H3 of the frame-shaped spacer 63 is the same as the height of the spacer 23B. This allows the frame-shaped spacer 63, similar to the spacer 23B, to function as an abutting surface of the vapor deposition mask 50. The end portion of the display region 61 corresponds to the spacing region 23C, in which no cover layer 23A is formed, and the cathode 25 is formed on the surface of the flattening film 21.

The frame-shaped spacer 63 is formed as an independent island pattern and is spaced apart from the cover layers 23A. Hence, similarly to the relationship between the cover layers 23A and the spacers 23B, it is easy to set the frame-shaped spacer 63 at a desired height. The frame-shaped spacer 63 is positioned in the same layer as the cover layers 23A and the spacers 23B, and is formed of the same organic photosensitive material in the same photolithography step as the cover layers 23A and the spacers 23B.

### Supplement

A display device according to Aspect 1 is a display device including: a plurality of picture elements; first electrodes; and cover layers, wherein the first electrodes are formed on the plurality of respective picture elements, each of the cover layers is configured to cover an outer periphery of a corresponding first electrode of the first electrodes, each of the cover layers allowing an opening of the corresponding first electrode to be formed, and a cover layers of the cover layers is spaced apart from a cover layer of the cover layers for a different first electrode of the first electrodes, the different first electrode being adjacent to the first electrode.

In a display device according to Aspect 2, a spacer formed in a same layer as the cover layers is provided between a plurality of the first electrodes, the spacer is higher than the cover layers, and an outer edge portion of the spacer is spaced apart from outer edge portions of the cover layers.

A display device according to Aspect 3 further includes a second electrode facing the first electrodes, wherein the first electrodes and the cover layers are formed on a surface of a flattening film, slits surrounding, in the flattening film, a display region including the plurality of picture elements are provided, to electrically communicate the second electrode and wiring lines of a thin-film transistor layer through the slits, and a frame-shaped spacer in the same layer as the cover layers is formed to surround the display region and the slits and is as high as the spacer.

An exposure device according to Aspect 4 is an exposure device for performing pattern formation by a photolithography method on a photosensitive organic material film covering a plurality of first electrodes formed on a surface of a flattening film, the exposure device including: a light source configured to emit light to expose the photosensitive organic material film; and a photomask configured to block part of the light from the light source, wherein the photomask includes a semi-transparent portion configured to block part of the light from the light source and a transparent portion configured to allow the light to pass through, the semi-transparent portion allows, for the plurality of first electrodes, openings of the first electrodes and cover layers each covering an outer periphery of corresponding first electrode of the first electrodes, to be formed by light passing through the semi-transparent portion, and the transparent portion allowing a spacing region to be formed by the light passing through the transparent portion, the spacing region spacing at least parts of a plurality of the banks apart from each other.

In an exposure device according to Aspect 5, the photomask further includes a light blocking portion configured to block the light, and the light blocking portion allows a spacer to be formed higher than the cover layers in a region between the plurality of first electrodes on the surface of the flattening film.

An exposure device according to Aspect 6 is an exposure device for performing pattern formation by a photolithography method on a photosensitive organic material film covering a plurality of first electrodes formed on a surface of a flattening film, the exposure device including: a light source configured to emit light to expose the photosensitive organic material film; and a photomask configured to block part of the light from the light source, wherein the photomask includes a semi-transparent portion configured to block part of the light from the light source and a light blocking portion configured to block the light, the semi-transparent portion allows, for the plurality of first electrodes, openings of the first electrodes and cover layers each covering an outer periphery of corresponding first electrode of the first electrodes, to be formed by light passing through the semi-transparent portion, and the light blocking portion allows a spacing region to be formed by blocking the light by the light blocking portion, the spacing region spacing at least parts of a plurality of the cover layers apart from each other.

In an exposure device according to Aspect 7, the photomask further includes a transparent portion configured to allow the light to pass through, and the transparent portion allows a spacer to be formed higher than the cover layers in a region between the plurality of first electrodes on the surface of the flattening film, by the light passing through the transparent portion.

A manufacturing method of a display device according to Aspect 8 includes: a photosensitive layer forming step of covering a plurality of first electrodes formed on a surface of a flattening film, with a photosensitive organic material; and a cover layer forming step of exposing the photosensitive organic material, by using a photomask blocking part of light from a light source, and thereafter developing the photosensitive organic material, and thereby forming cover layers each covering an outer periphery of a corresponding first electrode of the plurality of first electrodes, the cover layer allowing an opening of the corresponding first electrode to be formed, wherein the photomask includes semi-transparent portions configured to block part of the light from the light source and a transparent portion configured to allow the light to pass through, and in the cover layer forming step, exposure is performed a plurality of times while changing a position of the photomask, and each of the cover layers is spaced apart from the cover layer of a different first electrode of the first electrodes, the different first electrode being adjacent to the first electrode.

An electro-optical element (an electro-optical element whose luminance and transmittance are controlled by an electric current) that is provided in a display device according to the present embodiment is not particularly limited thereto. Examples of the display device according to the present embodiment include an organic Electro Luminescence (EL) display provided with the Organic Light Emitting Diode (OLED) as the electro-optical element, an inorganic EL display provided with an inorganic light emitting diode as the electro-optical element, and a Quantum dot Light Emitting Diode (QLED) display provided with a QLED as the electro-optical element.

### REFERENCE SIGNS LIST

2 Display device
21 Flattening film
22 Anode (first electrode)
23A Cover layer
23B Spacer
23C Spacing region
25 Cathode (second electrode)
29 Subpixel (picture element)
33 Exposure device
40, 40A Photomask
41 Semi-transparent region (semi-transparent portion)
42, 43A, 44A Light blocking region (light blocking portion)
42A, 43, 44 Transparent region (transparent portion)

1. A display device comprising:
a plurality of picture elements;
first electrodes; and
cover layers,
wherein the first electrodes are formed on the plurality of respective picture elements,
each of the cover layers is configured to cover an outer periphery of a corresponding first electrode of the first electrodes, each of the cover layers allowing an opening of the corresponding first electrode to be formed, and
a cover layer of the cover layers is spaced apart from a cover layer of the cover layers for a different first electrode of the first electrodes, the different first electrode being adjacent to the first electrode.

2. The display device according to claim 1,
wherein a spacer formed in a same layer as the cover layers is provided between a plurality of the first electrodes,
the spacer is higher than the cover layers, and
an outer edge portion of the spacer is spaced apart from outer edge portions of the cover layers.

3. The display device according to claim 2 further comprising
a second electrode facing the first electrodes,
wherein the first electrodes and the cover layers are formed on a surface of a flattening film,
slits surrounding, in the flattening film, a display region including the plurality of picture elements are provided, to electrically communicate the second electrode and wiring lines of a thin-film transistor layer through the slits, and
a frame-shaped spacer in the same layer as the cover layers is formed to surround the display region and the slits and is as high as the spacer.

4. An exposure device for performing pattern formation by a photolithography method on a photosensitive organic material film covering a plurality of first electrodes formed on a surface of a flattening film, the exposure device comprising:
a light source configured to emit light to expose the photosensitive organic material film; and
a photomask configured to block part of the light from the light source,
wherein the photomask includes a semi-transparent portion configured to block part of the light from the light source and a transparent portion configured to allow the light to pass through,
the semi-transparent portion allows, for the plurality of first electrodes, openings of the first electrodes and cover layers each covering an outer periphery of corresponding first electrode of the first electrodes, to be formed by light passing through the semi-transparent portion, and
the transparent portion allowing a spacing region to be formed by the light passing through the transparent portion, the spacing region spacing at least parts of a plurality of the cover layers apart from each other.

5. The exposure device according to claim 4,
wherein the photomask further includes a light blocking portion configured to block the light, and
the light blocking portion allows a spacer to be formed higher than the cover layers in a region between the plurality of first electrodes on the surface of the flattening film.

6. (canceled)

7. (canceled)

8. A manufacturing method of a display device, the manufacturing method comprising:
a photosensitive layer forming step of covering a plurality of first electrodes formed on a surface of a flattening film, with a photosensitive organic material; and
a cover layer forming step of exposing the photosensitive organic material, by using a photomask blocking part of light from a light source, and thereafter developing the photosensitive organic material, and thereby forming cover layers each covering an outer periphery of a corresponding first electrode of the plurality of first electrodes, the cover layer allowing an opening of the corresponding first electrode to be formed,
wherein the photomask includes semi-transparent portions configured to block part of the light from the light source and a transparent portion configured to allow the light to pass through, and
in the cover layer forming step, exposure is performed a plurality of times while changing a position of the photomask, and each of the cover layers is spaced apart from the cover layer of a different first electrode of the first electrodes, the different first electrode being adjacent to the first electrode.
